(19) United States
(12) Patent Application Publication
(10) Pub. No.: US 2025/0167186 A1
(43) Pub. Date: May 22, 2025

(54) Efficient Fan-Out (FO) Space Utilization in Package-On-Package (POP) Assemblies

(71) Applicant: Google LLC, Mountain View, CA (US)

(72) Inventor: Li-Sheng Weng, San Diego, CA (US)

(73) Assignee: Google LLC, Mountain View, CA (US)

(21) Appl. No.: 18/945,365

(22) Filed: Nov. 12, 2024

Related U.S. Application Data
(60) Provisional application No. 63/600,421, filed on Nov. 17, 2023.

(51) Int. Cl. H01L 25/16; H01L 23/498; H01L 23/538

(52) U.S. Cl. CPC H01L 25/162; H01L 23/49811; H01L 23/5385; H10D 1/68

(57) ABSTRACT

Package-on-package (POP) manufacturing combines the cost efficiencies of using separate packages with the space efficiencies of stacking integrated circuit (IC) chips. It can be difficult, however, to provide sufficient decoupling capacitance for those package(s) that do not form a base package coupled to a printed circuit board (PCB). In example implementations, the base package includes a decoupling capacitor disposed in a fan-out space in a same layer as an IC chip that is part of the base package. The decoupling capacitor can be electrically coupled to a power distribution network for an upper package to reduce voltage droop. Reducing voltage droop becomes more important for upper packages that include processing logic, such as a memory device with in-memory processing. In some cases, an interconnect via for the upper package and the decoupling capacitor can be adjacent to each other in the IC chip layer to further increase efficient space utilization.

### CROSS-REFERENCE TO RELATED APPLICATION(S)

This application claims the benefit of U.S. Provisional Patent Application No. 63/600,421 that was filed on 17 Nov. 2023, the disclosure of which is incorporated by reference herein in its entirety.

### BACKGROUND

Computing and other electronic devices play integral roles in manufacturing, communication, transportation, healthcare, commerce, social interaction, entertainment, and other services. For example, electronic devices power the server farms that provide cloud-based, distributed computing functionality for commerce, communication, and large-scale or high-demand artificial intelligence (AI) technologies. Electronic devices are also embedded in many different types of modern equipment, from medical devices to appliances and from vehicles to industrial tools. Personal electronic devices enable portable video viewing, convenient smart digital assistants, and access to AI services. Additionally, one versatile electronic device—the smartphone—has practically become a necessity to have within arm's reach.

To provide these diverse services and functionalities, electronic devices typically include various components, such as processors, memories, buses, fundamental passive components, and so forth. Some of these components may be realized with one or more integrated circuit (IC) chips, which may be packaged for use in an electronic device. Manufacturing an electronic device entails interconnecting and powering the various components, including packaged IC chips. The interconnections are often made using a printed circuit board (PCB) in view of spatial constraints arising from a finite volume allocated for the electronic device. The allocated volume may be finite due to an enclosed housing of the electronic device and/or a desire to aggregate multiple PCBs into a smaller space. Accordingly, computer engineers, electrical engineers, and other designers of electronic devices endeavor to improve the operation and/or architecture of the various components of an electronic device to facilitate their use in efficiently providing services.

### SUMMARY

This document describes hardware and techniques that enable efficient space utilization in a fan-out (FO) area of a package-on-package (POP) assembly. For example, a PoP assembly can have two packages: a first package and a second package “stacked on” the first package, with the first package configured to be coupled closer to (e.g., mounted on) a printed circuit board (PCB) as a “base” package. In some cases, an area occupied by an integrated circuit (IC) chip of the first package is less than an area occupied by the first package. Accordingly, there can be underutilized space between the second package and the PCB, with this underutilized space being “next to” the IC chip of the first package in the fan-out space (e.g., in an IC chip layer of the first package). Described implementations dispose at least one circuit component in this space within the first package for use with an IC chip of the second package. Thus, such a circuit component may be encased in molding of the first package but electrically coupled to the logic of the second package.

In example implementations, the at least one circuit component can include a passive fundamental circuit component, such as an inductor, a resistor, a capacitor, or any combination of one or more of these passive components. For instance, the at least one circuit component can include at least one capacitor. The at least one capacitor may further be realized as at least one decoupling capacitor (decap) or at least one bypass capacitor. Accordingly, the capacitor may be coupled to a power delivery network (PDN) or a voltage/power rail thereof for the circuitry of the second package. In some of such cases, the capacitor can provide a decoupling functionality for the load in the second package. As described herein, the load may correspond to an IC chip of the second package while the decoupling capacitor is included within the first package.

Generally, this document describes hardware and techniques that enable the components of electronic devices to interoperate under more stringent specifications, such as at higher frequencies, in a space-efficient form factor. Memory devices operate and communicate over buses at ever-increasing frequencies to improve data bandwidth. At times, a sudden power draw can cause a supply voltage to droop by an amount that adversely impacts memory performance. To address this situation, a decoupling capacitor, which is also referred to as a “decap,” can be coupled to a PDN of the memory. Because the decoupling capacitor stores charge, the decoupling capacitor can counteract the voltage drooping by releasing charge to support a specified supply voltage level. A finite length of time elapses while the charge propagates from the decoupling capacitor to the PDN of the memory. Consequently, the physical location of a decoupling capacitor can impact how effective the capacitor is at resisting the voltage droop.

In PoP assembly, a second package is coupled to a first package in a stacked arrangement. This arrangement complicates the interconnect and wire routing for the two packages and reduces the potential locations for physically positioning a decoupling capacitor, especially one for an “upper” package. By way of example only, a POP assembly may include a processing device, such as a main processor or a system-on-chip (SoC), in one package and a memory device in another package. In some cases, the processing device is mounted on a PCB or other support structure as a base package, and the memory device is mounted “on top of” the processing device as an upper package of one or more upper packages. For clarity, relative terms such as “on” and “under” are used herein in the context of the PCB or other support structure being at the bottom or lowest level of the component stack and therefore “below” the POP assembly. Nonetheless, a PoP assembly, a support structure therefor, or a housing of an electronic device can be rotated into other orientations relative to the earth's surface.

The effectiveness of a decoupling capacitor for the memory device is becoming more important as processing or logic functions are incorporated into memory devices, including by being integrated into memory chips. For example, processor-in-memory (PIM) and accelerator-in-memory (AiM) are being developed to support in-memory or near-memory processing paradigms. These near-memory processing paradigms can facilitate, for instance, AI and machine learning (ML) technologies. This document describes example locations for positioning at least one decoupling capacitor for the memory device that efficiently utilize the architecture of a PoP assembly. By way of example only, some example implementations are described in terms of a processing device being included in one package and a memory device being included in another package. The described principles are applicable, however, to other implementations with other circuitries and other organizations.

In example implementations, a decoupling capacitor can be positioned in the same layer as a processor of the first package. For instance, the processor and at least one decoupling capacitor for the memory device may be disposed between two redistribution layers of a base package. To accommodate the processing and logic functionality that is positioned near the memory in an upper package, these example locations can provide faster response times compared to potential locations that are farther from the memory device. These example locations can also avoid adding customization costs and avoid increasing the form factor of a POP assembly by disposing a decoupling capacitor in an underutilized space of a fan-out portion of the POP assembly.

In some implementations, the processor and associated processor layer is “sandwiched” between two redistribution layers (RDLs): a first redistribution layer and a second redistribution layer. From a top-down perspective, an area occupied by the two redistribution layers is greater than an area of the processor. To occupy a greater area, the redistribution layers can have first and second dimensions with one or both such dimensions being greater than the corresponding first and second dimensions of the processor. In cases in which at least one dimension is greater, there can be space (e.g., an area or a volume) between an edge of the processor and an edge of the redistribution layers along the same dimension. This fan-out space can be available for positioning at least one decoupling capacitor.

In some cases, a fan-out space may be devoid of interconnect vias, so a capacitor can be disposed anywhere in such spaces. This capacitor can therefore be efficiently incorporated in a PoP assembly without increasing the PCB area occupied by the assembly. In other cases, a fan-out space may include one or more interconnect vias. With respect to a fan-out volume that does include interconnect vias, at least one decoupling capacitor can be disposed in any one or more example “zones.” Two of such zones include being closer to a processor edge than an interconnect via and being farther from the processor edge than the interconnect via. Another zone for disposing the capacitor can be at least partially defined by a line or area extending between two interconnect vias along a dimension that is perpendicular to the processor edge, with this zone being located between the two interconnect vias. Still another example zone can include the capacitor and an interconnect via overlapping at least partially by being disposed at different points along a line that is parallel to the processor edge. With these various zones, a decoupling capacitor or other passive component can efficiently share space with one or more interconnect vias that service the memory device in an upper package without increasing the PCB area occupied by the POP assembly.

In these manners, a capacitor for a second package of a PoP assembly can be disposed in a first package of the POP assembly. For example, at least one decoupling capacitor can be disposed between two redistribution layers of the first package, such as in the same layer as an IC chip of the first package. This location provides superior performance compared to positioning the decoupling capacitor between the first package and a support structure, such as a PCB, or directly on the support structure. The superior performance can enable, for example, voltage droop remediation to be effective at higher frequencies. This location is also less costly than disposing the decoupling capacitor between the first and second packages of the POP assembly. Further, a capacitor can be positioned between an edge of the IC chip of the first package and an edge of the redistribution layers thereof, which may may align with an edge of the first package, to efficiently utilize a volume provided by the fan-out space of the first package. For example, a decoupling capacitor can be positioned between the edge of the IC chip of the first package and a “first” interconnect via (“first” relative to a direction starting at the IC chip edge and extending toward the first package edge), with the “first” interconnect via used by an IC chip of the second package.

In example implementations, an apparatus for efficient space utilization with a package-on-package (POP) assembly is described. The apparatus includes a first package having a first side and a second side, with the first side configured to be connected to a support structure. The first package includes a first integrated circuit (IC) chip that defines a chip layer of the first package, with the first IC chip having a chip edge. The first package also includes an interconnect via disposed in the chip layer. The first package further includes a capacitor disposed in the chip layer, with the capacitor and the interconnect via disposed along a line that is substantially perpendicular to the chip edge of the first IC chip. The apparatus also includes a second package having a first side, with the first side of the second package configured to be connected to the second side of the first package and with the second package including a second IC chip.

In example implementations, a method for manufacturing a space-efficient package-on-package (PoP) assembly is described. The method includes providing a first package having a first side and a second side, with the first side configured to be connected to a support structure. The first package includes a first integrated circuit (IC) chip that defines a chip layer of the first package, with the first IC chip having a chip edge. The first package also includes an interconnect via disposed in the chip layer. The first package further includes a capacitor disposed in the chip layer. The capacitor and the interconnect via are disposed along a line that is substantially perpendicular to the chip edge of the first IC chip. The method also includes providing a second package having a first side, with the first side of the second package configured to be connected to the second side of the first package. The second package includes a second IC chip.

In example implementations, an apparatus for efficient space utilization with a package-on-package (POP) assembly is described. The apparatus includes a support structure, a first package, and a second package. The first package has a first side and a second side, with the first side connected to the support structure. The first package includes a package edge, a first redistribution layer disposed closer to the first side than the second side, a second redistribution layer disposed closer to the second side than the first side, and a chip layer disposed between the first redistribution layer and the second redistribution layer. The chip layer includes a first integrated circuit (IC) chip having a chip edge that is substantially parallel to the package edge. The chip layer also includes an interconnect via disposed between the chip edge and the package edge. The chip layer further includes a decoupling capacitor disposed between the chip edge and the package edge. The decoupling capacitor and the interconnect via are disposed along a line that is substantially perpendicular to the chip edge and the package edge. The second package has a first side, with the first side of the second package connected to the second side of the first package. The second package includes a second IC chip that is coupled to the decoupling capacitor.

In example implementations, an apparatus for space-efficient package-on-package (POP) assembly is described. The apparatus includes a first package and a second package. The first package includes first circuitry, a first side, a second side, and at least one circuit component, with the first side configured to be coupled to a printed circuit board (PCB). The second package includes second circuitry and a first side, with the first side of the second package coupled to the second side of the first package. The at least one circuit component is coupled to the second circuitry of the second package.

In example implementations, a method for operating a space-efficient package-on-package (PoP) assembly is described in which a capacitor disposed in a first package functions as a decoupling capacitor for circuitry disposed in a second package. Other implementations are described herein.

### BRIEF DESCRIPTION OF DRAWINGS

Apparatuses of and techniques for efficient fan-out (FO) space utilization in package-on-package (POP) assemblies are described with reference to the following drawings. The same numbers are used throughout the drawings to reference like features and components.

FIG. 1 illustrates an example apparatus with at least one package-on-package (PoP) assembly that includes first and second packages and a capacitor and that can implement efficient fan-out space utilization in a PoP assembly.

FIG. 2 illustrates a top-down view of an example PoP assembly that is mounted on a support structure.

FIG. 3 illustrates a cross-section view of the example PoP assembly that is mounted on the support structure in FIG. 2 and that includes an example chip layer from the perspective of a front or side view.

FIGS. 4-1 and 4-2 illustrate two cross-section views of example chip layers of FIG. 3 from a top-down perspective, with the chip layers including interconnect vias in at least one fan-out region.

FIG. 5 illustrates a cross-section view of an example PoP assembly of FIG. 3 that depicts interconnect vias in the chip layer in conjunction with at least one capacitor from the perspective of a front view.

FIGS. 5-1 to 5-3 illustrate with a cross-section view example POP assemblies of FIG. 5 that depict different example implementations for interconnect vias and capacitors in the chip layer.

FIG. 6 illustrates a cross-section view of an example PoP assembly of FIG. 3 that depicts the absence of interconnect vias in the chip layer in conjunction with at least one capacitor from the perspective of a side view.

FIG. 6-1 illustrates with a cross-section view an example PoP assembly of FIG. 6 that depicts an example implementation for capacitors in the chip layer.

FIG. 7 illustrates a cross-section view of an example PoP assembly with a base package including an SoC and an upper package including a memory device.

FIG. 8 is a flow diagram illustrating an example process for manufacturing a PoP assembly that efficiently utilizes fan-out space.

FIG. 9 illustrates various components of an example electronic device that can implement efficient fan-out space utilization in PoP assemblies in accordance with one or more described aspects.

### DETAILED DESCRIPTION

### Overview

Electronic devices provide features and perform functions to make important contributions to modern society, such as those related to communication, safety, manufacturing, content creation, and information technology generally. These contributions entail two or more components of an electronic device communicating with each other to interoperate properly. This document describes hardware and techniques that enable the components of electronic devices to interoperate under more-stringent specifications, such as at higher frequencies, in a space-efficient form factor.

Memory devices, for example, operate and communicate over buses at ever-increasing frequencies to improve data bandwidth. At times, a sudden power draw can cause a supply voltage to droop by an amount that adversely impacts memory performance. To address this situation, a decoupling capacitor, which is also referred to as a “decap,” can be coupled to a power distribution network (PDN) for the memory. Because the decoupling capacitor stores charge, the decoupling capacitor can counteract the droop tendency by releasing charge to support a specified supply voltage level. A finite length of time elapses while the charge propagates from the decoupling capacitor to the PDN of the memory. Consequently, the physical location of a decoupling capacitor can impact how effective the capacitor is at resisting the voltage droop.

In a package-on-package (POP) assembly, a second package is coupled to a first package in a stacked arrangement. This arrangement complicates the interconnect and wire routing for the two packages and reduces the potential locations for physically positioning a decoupling capacitor. By way of example only, a POP assembly may include a processing device, such as a main processor or a system-on-chip (SoC), in one package and a memory device in another package. In some cases, the processing device is mounted on a printed circuit board (PCB) or other support structure as a base package, and the memory device is mounted “on top of” the processing device as an upper package of one or more upper packages. For clarity, relative terms such as “on” and “under” are used herein in the context of the PCB or other support structure being at the bottom or lowest level of the component and therefore “below” the POP assembly. Nonetheless, a PoP assembly, a support structure therefor, or a housing of an electronic device can be rotated into other orientations relative to the earth's surface.

There are several potential locations for positioning a decoupling capacitor that is to be electrically coupled to an integrated circuit (IC) chip of an upper package, such as a memory device, of a PoP assembly. In a first potential location, a decoupling capacitor for the memory device may be positioned under the memory device to be disposed between the memory device and the base package, such as a processing device. This location may be referred to as the “backside” of the memory package. Utilizing this location, however, entails creating a custom mapping for the ball grid array (BGA) of the memory device, and this customization involves additional costs.

In a second potential location, a decoupling capacitor for the memory device may be positioned under the processing device to be disposed between the processing device and the support structure, such as a PCB. This location may be referred to as the “backside” of the processing package. By consuming the scarce area that is available for the BGA of the processing device, this location likely increases the form factor of the processing package and thus that of the PoP assembly. Further, the mitigation of the voltage droop resulting from this second potential location is less effective as compared to the mitigation resulting from the first potential location because the decoupling capacitor is coupled farther from the memory device.

In a third potential location, a decoupling capacitor for the memory device may be positioned on the PCB. (This decoupling capacitor may be in addition to other decoupling capacitors also mounted on the PCB.) By being mounted on the PCB, however, the decoupling capacitor is still farther from the memory device because such a decoupling capacitor is no longer part of the PoP assembly. Consequently, the voltage droop mitigation is even less effective with this third potential location as compared to the second potential location due to the increasing distance between the decoupling capacitor and the memory chips of the memory device.

The effectiveness of a decoupling capacitor for the memory device is becoming more important as processing or logic functions are incorporated into memory devices, including by being integrated into memory chips. For example, processor-in-memory (PIM) and accelerator-in-memory (AiM) are being developed to support in-memory or near-memory processing paradigms. These near-memory processing paradigms can facilitate, for instance, AI and machine learning (ML) technologies. To operate the processing and other logic circuitries, the profile of the current for the “memory” device is shifting toward a higher frequency domain. To meet the resulting specifications, the voltage droop requirements on the supply voltage will be more stringent. Consequently, a decoupling capacitor solution will be expected to accommodate the higher frequency demands of the processing and other logic circuitries.

This document describes other example locations for positioning at least one decoupling capacitor for the memory device. In example implementations, a decoupling capacitor can be positioned in the same layer as a processor of the processing device. For instance, the processor and at least one decoupling capacitor for the memory device may be disposed between two redistribution layers of a base package. To accommodate the processing and logic functionality that is positioned near the memory in an upper package, these example locations can provide faster response times compared to the second and third potential locations for a decoupling capacitor as described above. These example locations can also avoid the added cost of relying on a custom ball map for the memory device like with the first potential location for a decoupling capacitor that is described above. Further, at least some of the described example locations for a decoupling capacitor can avoid increasing the form factor of a PoP assembly by disposing a decoupling capacitor in an underutilized space of a fan-out (FO) portion of the POP assembly.

In some implementations, the processor and associated processor layer is “sandwiched” between two redistribution layers (RDLs): a first redistribution layer and a second redistribution layer. From a top-down perspective, an area occupied by the two redistribution layers is greater than an area of the processor. To occupy a greater area, the redistribution layers can have first and second dimensions with one or both such dimensions being greater than the corresponding first and second dimensions of the processor. In cases in which at least one dimension is greater, there can be space (e.g., an area or a volume) between an edge of the processor and an edge of the redistribution layers along the same dimension. This fan-out space can be available for positioning at least one decoupling capacitor.

With a third dimension introduced by the height of the processor, there can be two pairs of volumes adjacent to the four edges of a processor, with each pair of volumes being on opposite sides of the processor. In some cases, a first pair of two fan-out volumes on opposite sides of the processor are unused for interconnect vias for the memory device and may be devoid of interconnect vias. A second pair of two fan-out volumes on different opposite sides of the processor are used for interconnect vias for the memory device. These interconnect vias may extend through the processor layer between the first and second redistribution layers. At least one decoupling capacitor may be disposed in, for example, any of these four volumes.

With respect to a fan-out volume that includes interconnect vias, at least one decoupling capacitor can be disposed in any one or more zones of three example zones. A first zone extends between an edge of the processor and a first interconnect via along a line or direction that extends perpendicular to the edge of the processor and toward an edge of the two redistribution layers, which may align with an edge of the base package. A second zone extends from the first interconnect via to a second interconnect via along the line. Thus, for the second zone, the decoupling capacitor is positioned to be between two interconnect vias along the line that is perpendicular to both edges.

A third zone extends from the “last” interconnect via to the edge of the two redistribution layers. In the third zone, the decoupling capacitor can be positioned between the “last” interconnect via and the edge of the two redistribution layers. In some cases, if a perpendicular line between the edge of the processor and the edge of the two redistribution layers includes only one interconnect via, then the “first” interconnect via and the “last” interconnect via collapse into a single interconnect via. A decoupling capacitor can be positioned in the second zone if it overlaps the single interconnect via in a line that runs parallel to the edge of the processor. A decoupling capacitor can also be in the second zone if it overlaps one of multiple interconnect vias along the direction that extends perpendicular to the edge of the processor. With these zones, the decoupling capacitor can efficiently share space with one or more interconnect vias that service the memory device in an upper package.

In these manners, a decoupling capacitor for a second package of a PoP assembly can be disposed in a first package of the POP assembly to efficiently utilize available space. For example, at least one decoupling capacitor can be disposed between two redistribution layers of the first package, such as in the same layer as an IC chip of the first package. This location provides superior performance compared to positioning the decoupling capacitor between the first package and a support structure, such as a PCB, or on the support structure. The superior performance can enable, for example, voltage droop remediation to be effective at higher frequencies. This location is also less costly than disposing the decoupling capacitor between the first and second packages of the POP assembly.

Further, a decoupling capacitor can be positioned between an edge of the IC chip of the first package and an edge of the redistribution layers thereof, and/or an edge of the first package, to efficiently utilize a volume provided by the fan-out space. For example, a decoupling capacitor can be positioned between the edge of the IC chip of the first package and a “first” interconnect via (“first” relative to a direction starting at the IC chip edge and extending toward the first package edge). The “first” interconnect via may be used by an IC chip of the second package. These and other example implementations are described herein.

### Example Environments and Electronic Devices

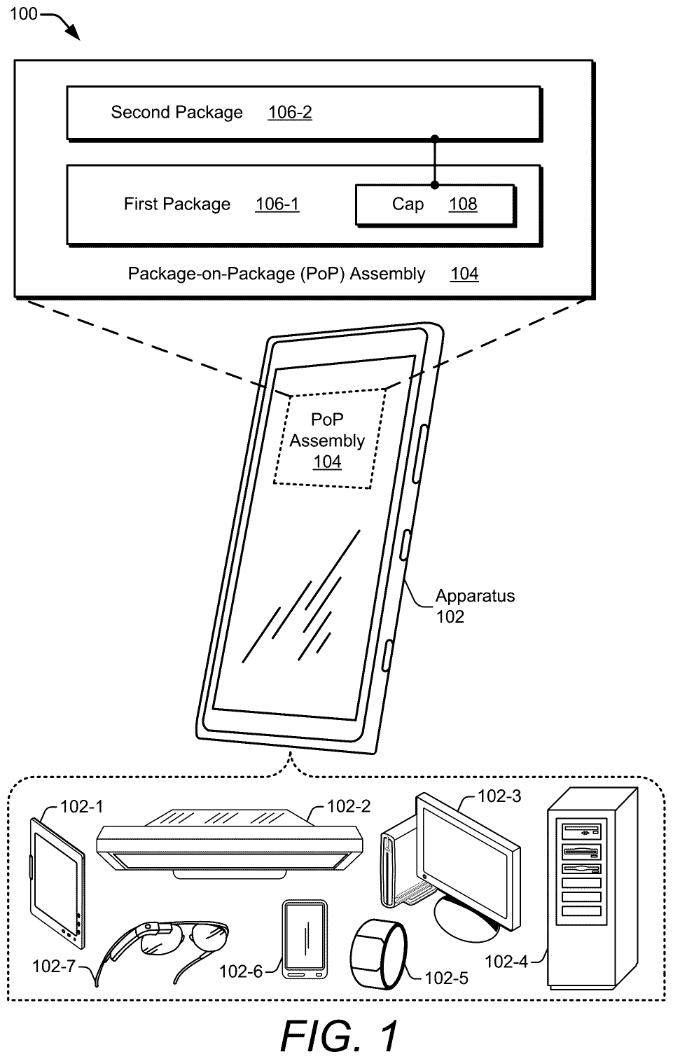

FIG. 1 illustrates, at 100 generally, an example apparatus 102 with at least one package-on-package (POP) assembly 104 (POP assembly 104) that includes a first package 106-1, a second package 106-2, and a capacitor 108 (cap 108) and that can implement efficient fanout space utilization in a PoP assembly. In example implementations, the POP assembly 104 can include multiple packages 106-1, 106-2, . . . 106-P (not shown), with “P” representing a positive integer greater than one. Thus, although the depicted examples of a PoP assembly 104 have two packages, a PoP assembly 104 can have more than two packages. The apparatus 102, the POP assembly 104, and/or at least one package 106 (e.g., the first package 106-1 with a capacitor 108) can implement efficient fanout space utilization in a PoP assembly as described herein. In some cases, the capacitor 108 may be implemented as a decoupling capacitor 108. Thus, in at least some implementations, the decoupling capacitor 108 of the first package 106-1 can be configured to be coupled to the second package 106-2 to provide decoupling capacitance to circuitry of the second package 106-2.

In this example, the apparatus 102 is depicted as a smartphone. The apparatus 102 may, however, be implemented as any suitable computing or other electronic device as described herein. Examples of the apparatus 102 include a mobile electronic device or mobile device, mobile communication device, modem, cellular or mobile phone, mobile station, gaming device, navigation device, media or entertainment device (e.g., a media streamer or gaming controller), laptop computer, desktop computer, tablet computer, smart appliance, vehicle-based electronic system, wearable computing device (e.g., clothing, watch, or reality-altering glasses), Internet of Things (IoTs) device, sensor, stock management device, electronic portion of a machine or piece of equipment (e.g., a vehicle or robot), memory storage device (e.g., a solid-state drive (SSD)), server computer or portion thereof (e.g., a server blade or rack or another part of a datacenter), and the like. Illustrated examples of the apparatus 102 include a tablet device 102-1, a smart television 102-2, a desktop computer 102-3, a server computer 102-4, a smartwatch 102-5, a smartphone (or document reader) 102-6, and intelligent glasses 102-7.

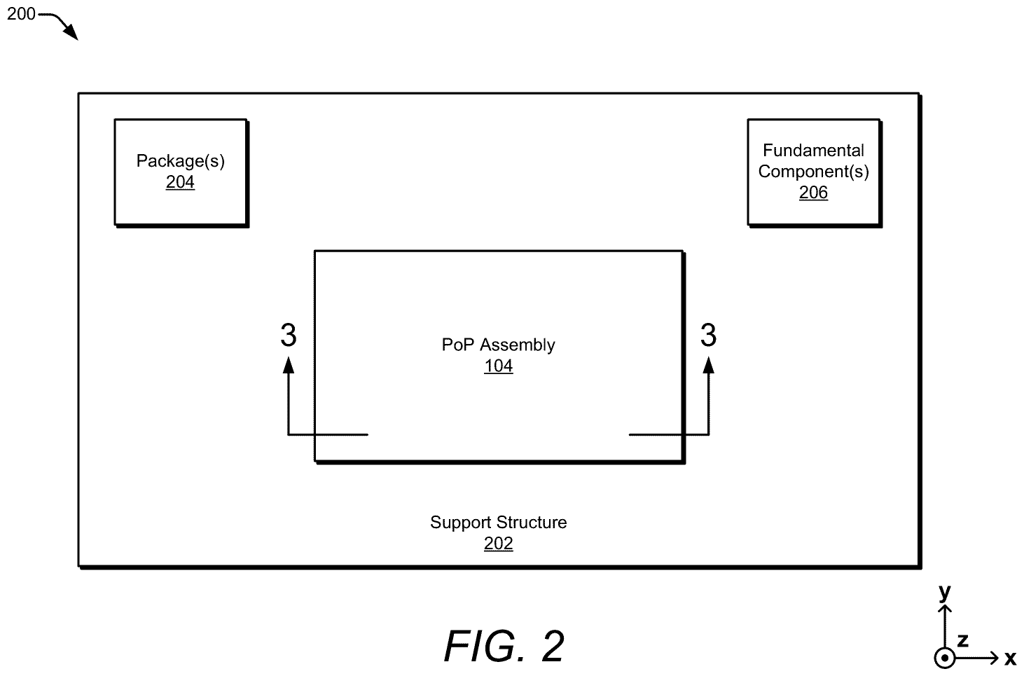

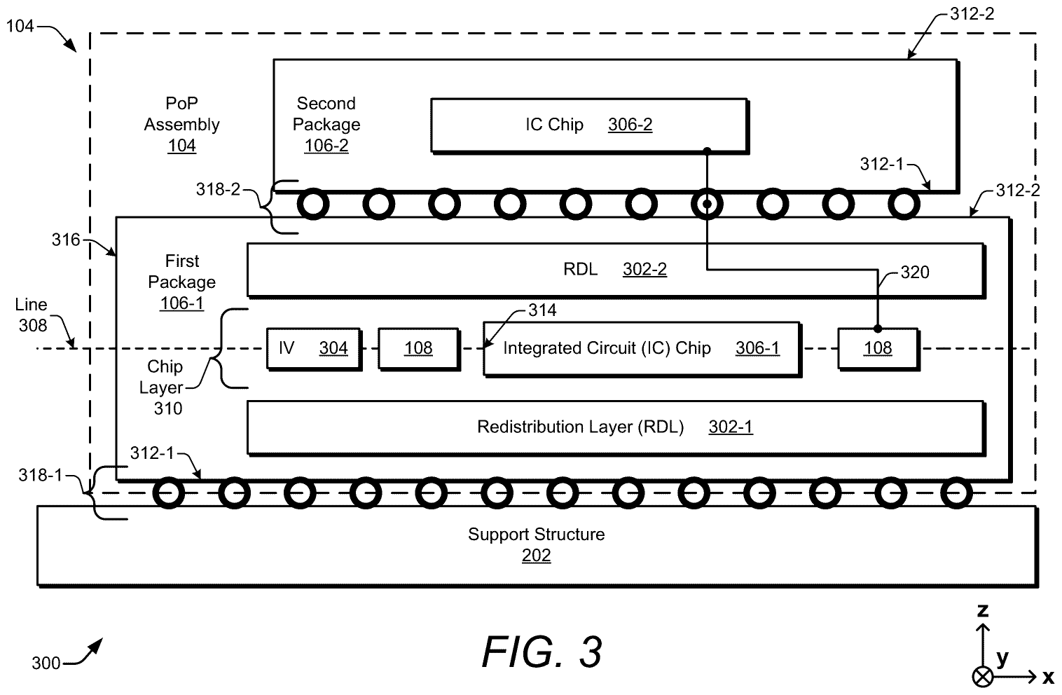

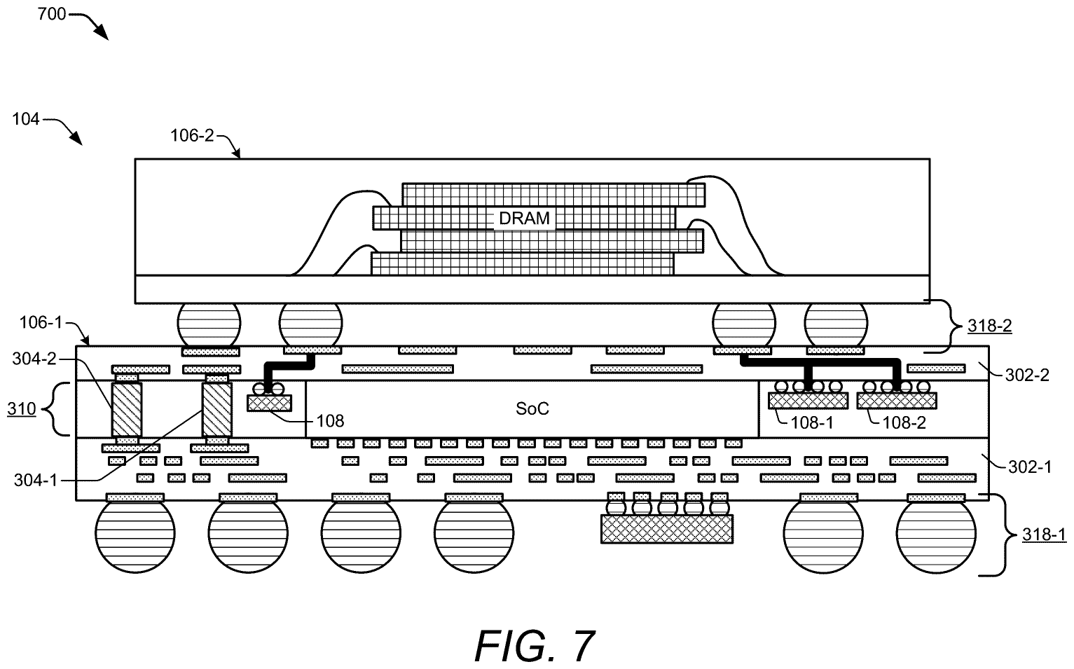

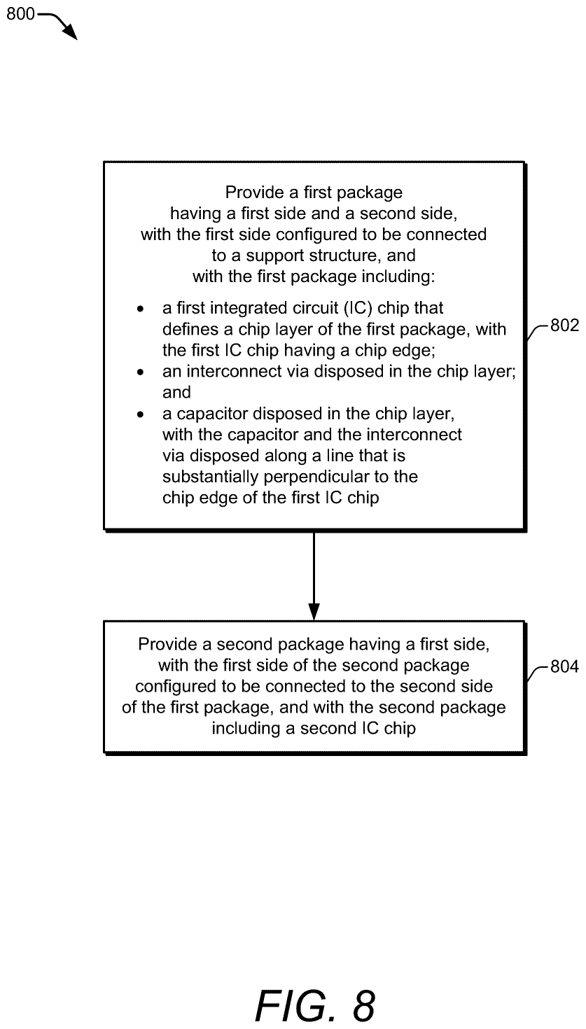

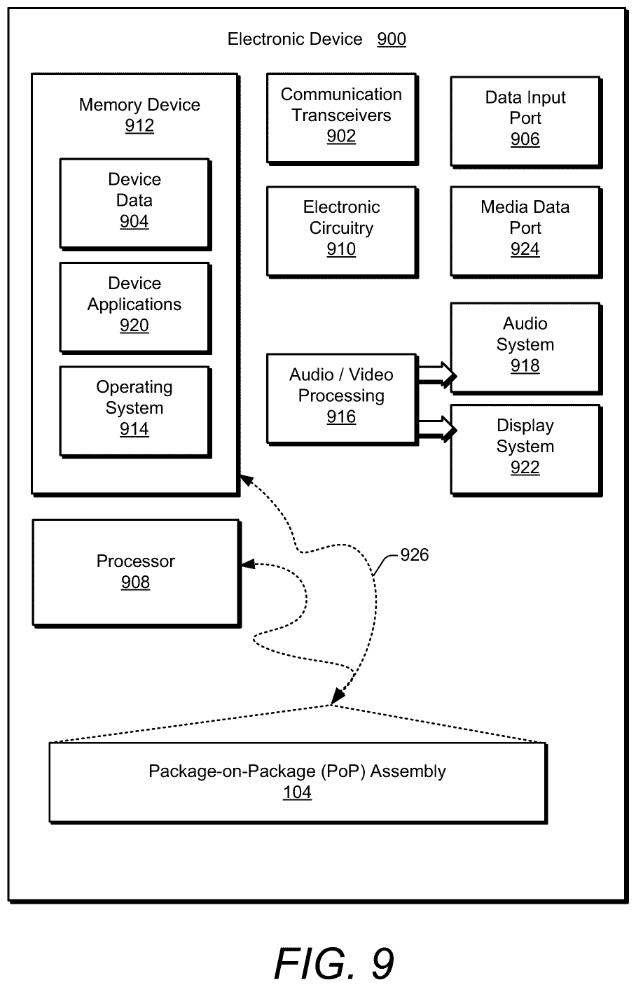

In example implementations, the apparatus 102 includes at least one PoP assembly 104. The PoP assembly 104 can be mounted on, or otherwise connected to, at least one support structure, such as a PCB (not shown in FIG. 1). Support structure examples are described below with reference to FIG. 2. Each package 106 can include at least one IC chip, examples of which are described herein with reference to FIGS. 3 and 7. Other example apparatus implementations are described with reference to FIGS. 4-1 to 6-1. Example methods of manufacturing a PoP assembly 104 are described with reference to FIG. 8. An electronic device that can implement efficient fan-out space utilization in a PoP assembly is described, by way of example only, with reference to FIG. 9.

### Example Apparatuses and Operational Schemes

FIG. 2 illustrates a top-down view 200 of an example PoP assembly 104 that is mounted on a support structure 202. As shown, the top-down view 200 includes the support structure 202. Examples of a support structure 202 include a printed circuit board (PCB), a printed wiring board (PWB), a printed circuit assembly (PCA), a circuit card assembly (CCA), a combination thereof, and so forth. Examples of a PCB (or other board or assembly) include a flexible PCB, a rigid PCB, a single or multi-layered PCB, a surface-mounted or through-hole PCB, combinations thereof, and so forth. Mounted on the support structure 202 are one or more packages 204, one or more fundamental components 206, and so forth. Although only one side of the support structure 202 is depicted, one or more other components may be mounted on the opposite side. The POP assembly 104 is shown in a particular location and in a particular orientation with respect to the support structure 202; however, the POP assembly 104 may be mounted in a different location, orientation, side, and so forth.

Three axes are included in FIG. 2. A first axis extends horizontally (as depicted) in a rightward direction and is labeled the “x-axis.” A second axis extends vertically (as depicted) in an upward direction and is labeled the “y-axis.” The first and second axes are in the plane of the drawing sheet. A third axis is perpendicular to the plane of the drawing sheet, extends outward from the page toward the viewer, and is labeled the “z-axis.” Each axis is perpendicular to the other two axes. The various blocks representing different components are not necessarily drawn to scale throughout the drawings. A cross-sectional view of the POP assembly 104 and the support structure 202 that is depicted in FIG. 3 is indicated in FIG. 2.

FIG. 3 illustrates, from the perspective of a front or side view, a cross-section view 300 of an example PoP assembly 104 that is mounted on a support structure 202 and that includes an example chip layer 310. At least some of the example aspects depicted in FIG. 3 can pertain to a front view or to a side view. More specific examples of front and side views are respectively shown in FIGS. 5 to 5-3 and 6 to 6-1 relative to the front and side views that are indicated in FIGS. 4-1 and 4-2. For FIG. 3, the three axes are consistent with those of FIG. 2. The x-axis extends horizontally and increases in a rightward direction. Due to the cross-section view 300, the axis that runs vertically upwards is the z-axis, and the y-axis therefore extends into the page and away from the viewer.

In example implementations, the cross-section view 300 includes the support structure 202, a first package 106-1, and a second package 106-2. The first package 106-1 has a first side 312-1 and a second side 312-2. The first side 312-1 is connected to the support structure 202. The connection may be effectuated with a first ball grid array 318-1. The first package 106-1 includes a package edge 316, a first redistribution layer 302-1, a second redistribution layer 302-2, and a chip layer 310. The first redistribution layer 302-1 is disposed closer to the first side 312-1 of the first package 106-1 than to the second side 312-2 of the first package 106-1. The second redistribution layer 302-2 is disposed closer to the second side 312-2 of the first package 106-1 than to the first side 312-1 of the first package 106-1.

The chip layer 310 is disposed between the first redistribution layer 302-1 and the second redistribution layer 302-2. The chip layer 310 includes a first integrated circuit (IC) chip 306-1 having a chip edge 314 that is substantially parallel to the package edge 316. The chip layer 310 also includes at least one interconnect via 304 (IV 304) and at least one capacitor 108. The interconnect via 304 is disposed in the chip layer 310 between the chip edge 314 of the first IC chip 306-1 and the package edge 316 of the first package 106-1. The capacitor 108 is also disposed in the chip layer 310 between the chip edge 314 and the package edge 316. The capacitor 108 may be realized as, for instance, a decoupling capacitor 108. As described herein, the capacitor 108 can instead be realized more generally as a passive fundamental component, such as an inductor, a resistor, or a capacitor.

In some cases, the capacitor 108 and the interconnect via 304 are disposed along a line 308 that is substantially perpendicular to the chip edge 314 and the package edge 316. To be disposed along the line 308, at least a portion of a component (e.g., a capacitor 108 or an interconnect via 304) lies or is otherwise located “over” the line 308. Thus, the capacitor 108 and the interconnect via 304 can overlap each other at least partially along the line 308 traveling from the chip edge 314 to the package edge 316 (or vice versa) for the capacitor 108 and the interconnect via 304 to be disposed along the line 308, which is substantially perpendicular to the chip edge 314 and the package edge 316 in this example. To provide ample volume for the capacitor 108, a height of the first IC chip 306-1 along the z-axis can be greater than a height of the capacitor 108. From an alternative perspective, to efficiently utilize the fan-out space around the first IC chip 306-1, a height of the capacitor 108 can be selected or sized to be less than a height of the first IC chip 306-1.

The second package 106-2 has a first side 312-1 and a second side 312-2. The first side 312-1 of the second package 106-2 is connected to the second side 312-2 of the first package 106-1. The connection may be realized using a second ball grid array 318-2. The second package 106-2 includes a second IC chip 306-2 that can be coupled to the capacitor 108. This coupling may be effectuated using an electrical pathway 320 that extends at least partially through the second redistribution layer 302-2. Other implementations may, however, include more or fewer components, may arrange the components differently, and so forth relative to the illustration of FIG. 3.

As used herein, “substantially” in terms of “substantially parallel” and “substantially perpendicular” can connote different ranges depending on context. For example, “substantially” can correspond to being as “parallel” or as “perpendicular” as is feasible given a particular technology's capabilities. As another example, “substantially” can connote being within 20%, 10%, 5%, or even 1% of being fully “parallel” or “perpendicular.”

The first and second IC chips 306-1 and 306-2 can be any circuitry and/or provide any circuit functionality. For example, an IC chip 306 can be realized as a general-purpose processor, a microcontroller, an application-specific IC (ASIC), and so forth. Other examples of IC chips include a system-on-a-chip (SoC), a security-oriented IC chip, a memory chip, a communications IC chip (e.g., a modem or radio-frequency IC), a graphics processor, an artificial intelligence (AI) accelerator, a sensor chip, a combination thereof, and so forth. Sensor chips may include, for example, an accelerometer, a camera or other light sensor, a satellite positioning system chip (e.g., a Global Positioning System (GPS) chip), and the like. An IC chip can be packaged alone or together with other IC chips.

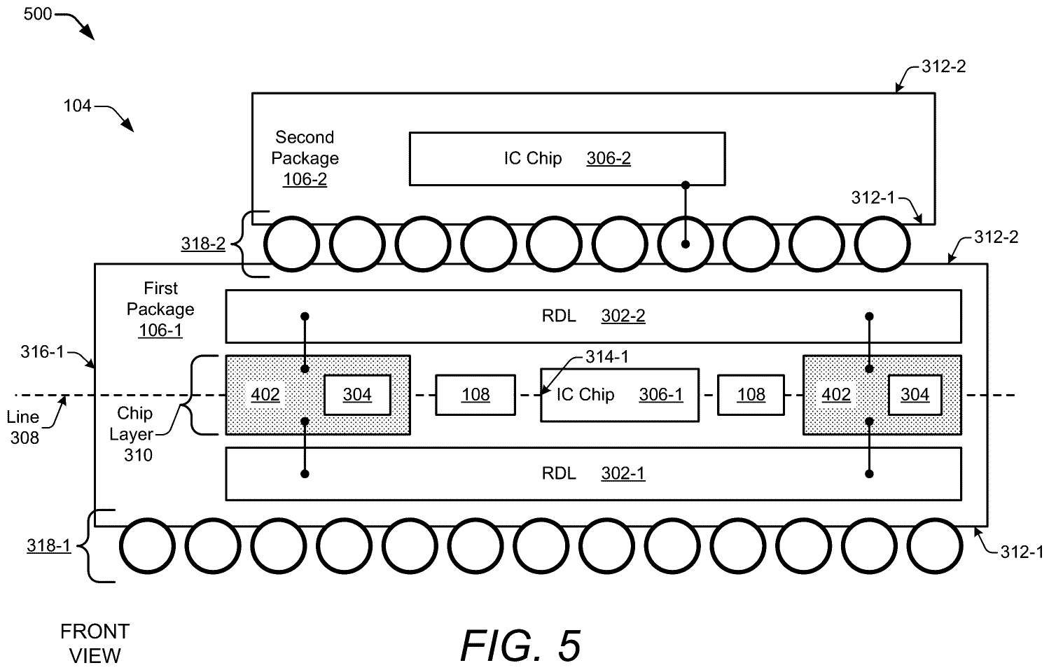

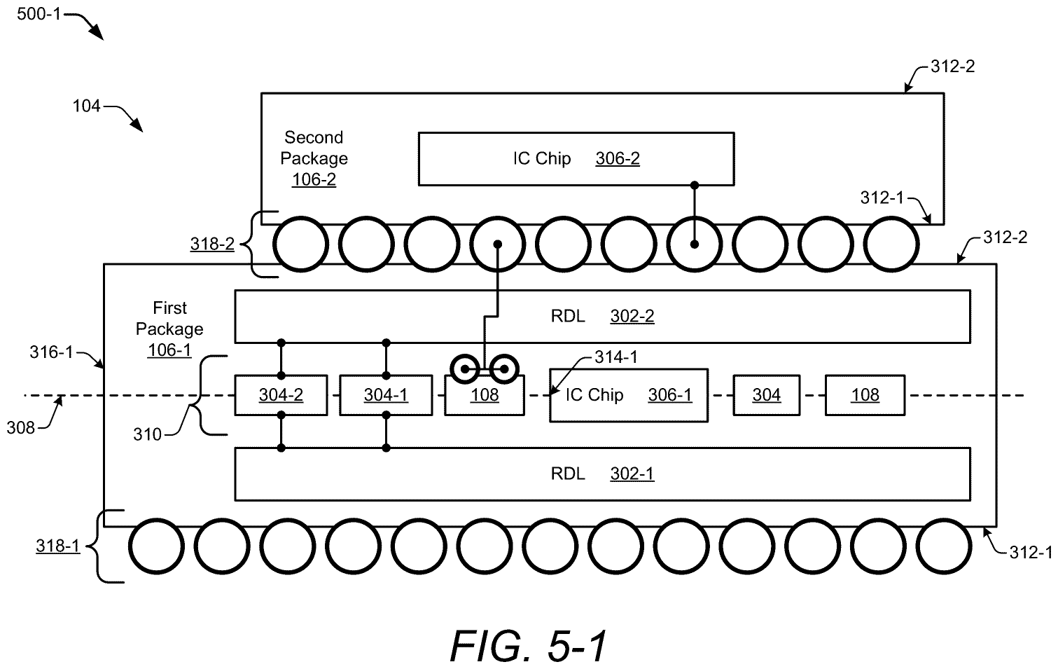

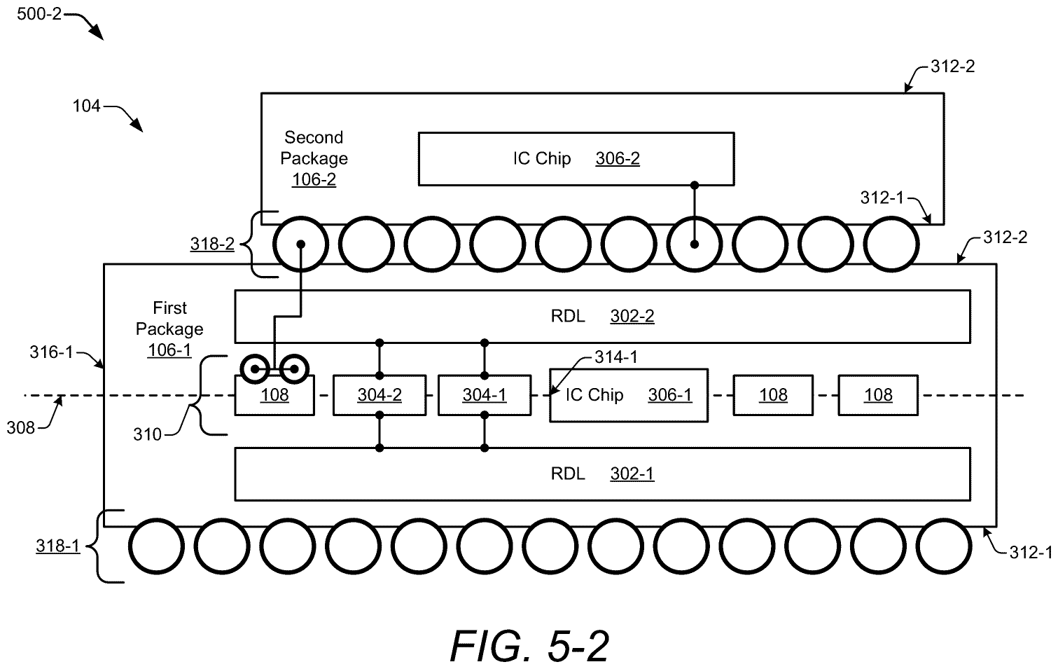

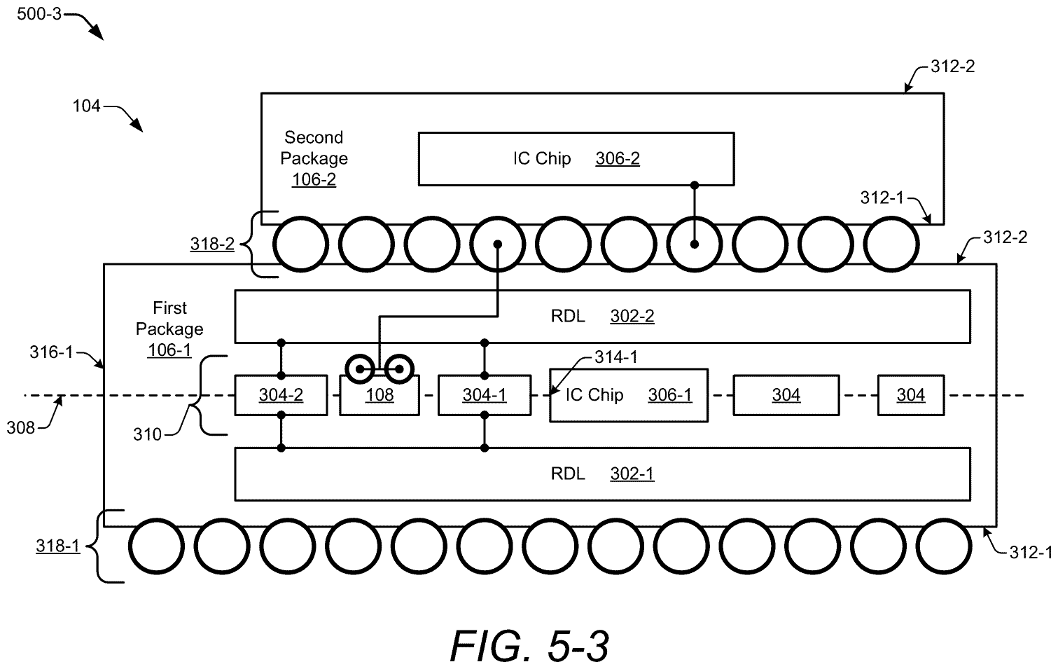

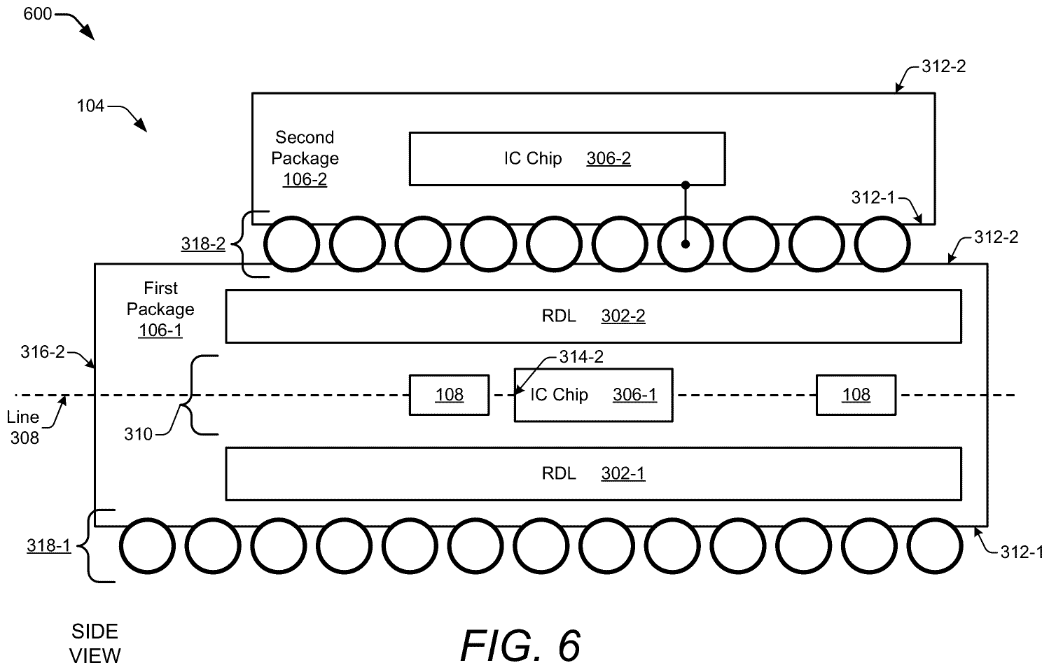

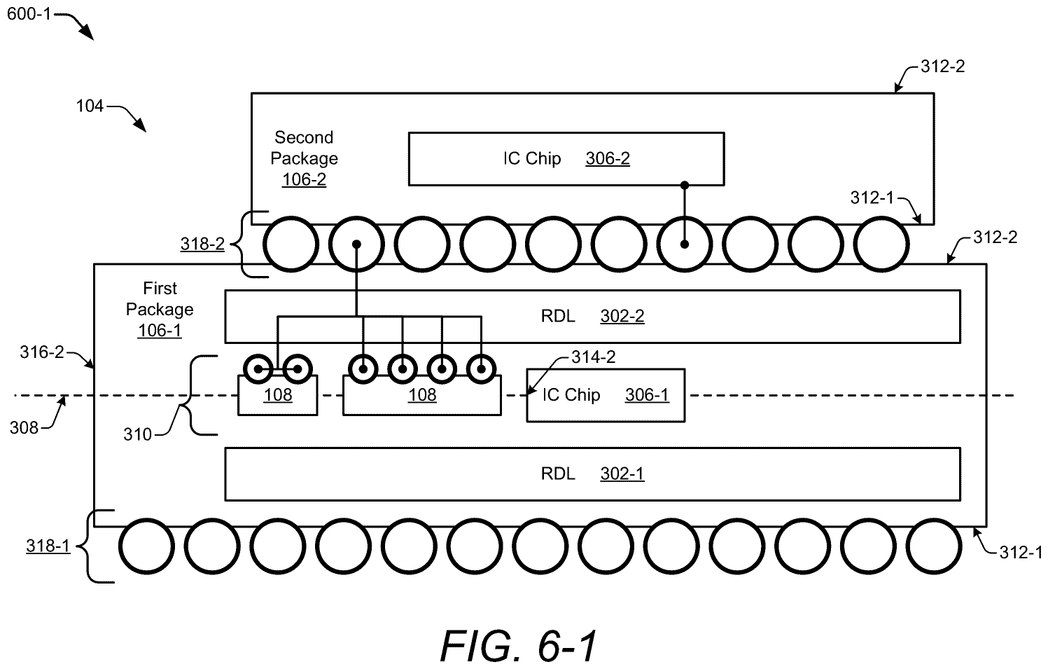

FIGS. 4-1 and 4-2 illustrate two cross-section views 400-1 and 400-2 of example chip layers 310 of FIG. 3 from a top-down perspective. The chip layers 310 include interconnect vias 304 in at least one fan-out region around the first IC chip 306-1. A front 408 and a side 410 of the first package 106-1 are indicated in FIGS. 4-1 and 4-2. The front 408 and the side 410 are respectively referenced below by FIG. 5, which shows a cross-sectional front view, and by FIG. 6, which shows a cross-sectional side view. The first IC chip 306-1 includes two first chip edges 314-1 that are substantially parallel to the side 410 and two second chip edges 314-2 that are substantially parallel to the front 408. The first package 106-1 includes two first package edges 316-1 that are substantially parallel to the side 410 and two second package edges 316-2 that are substantially parallel to the front 408.

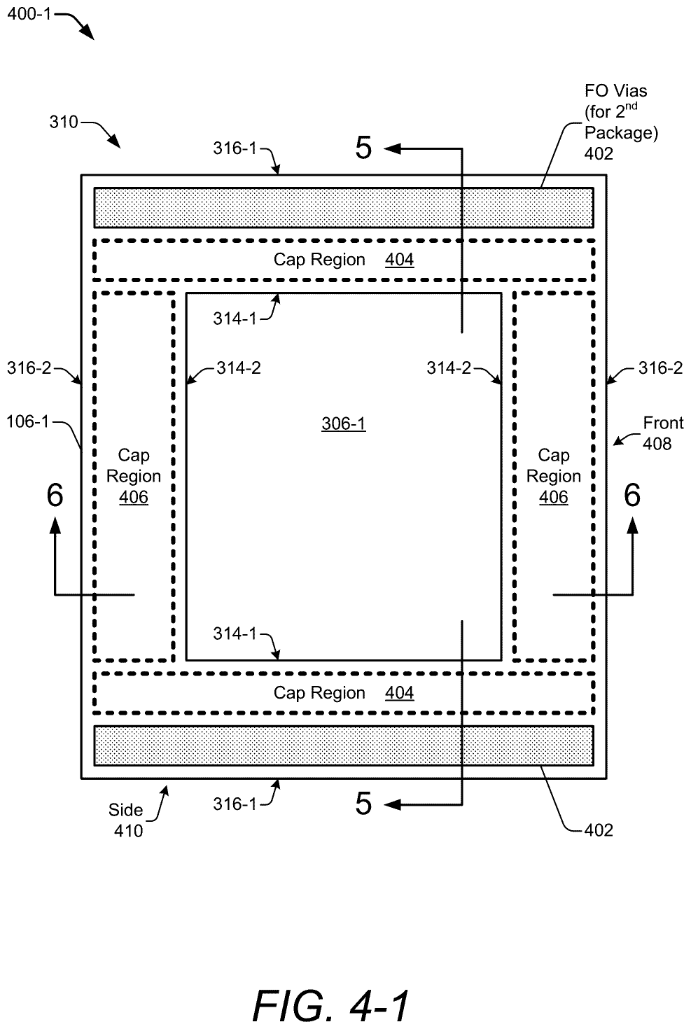

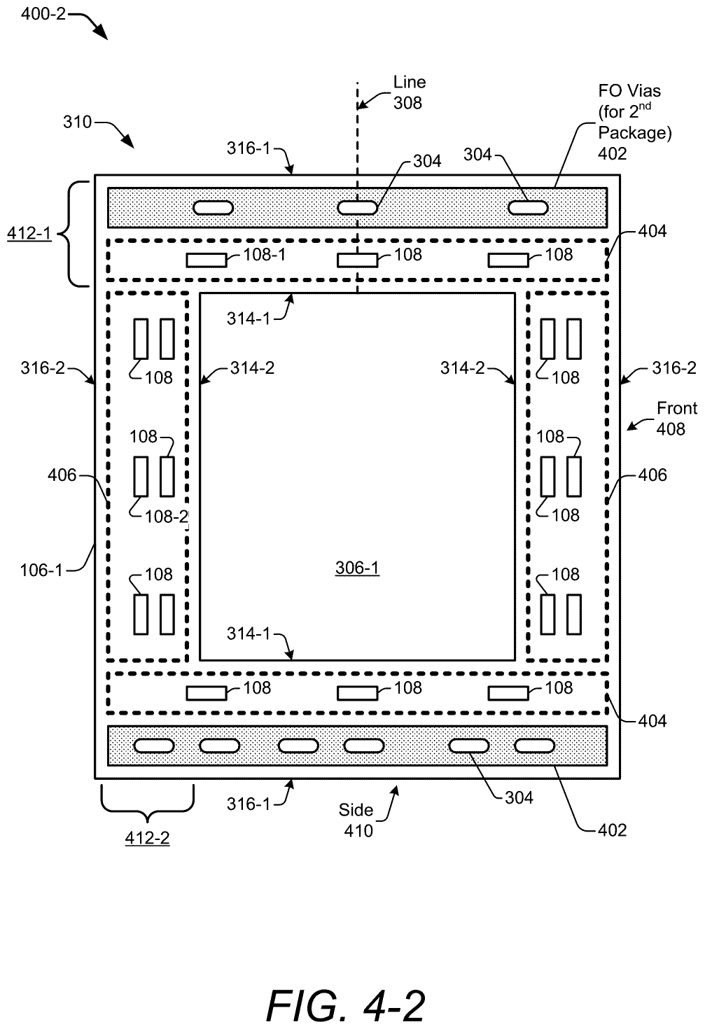

As shown in the cross-section view 400-1, the chip layer 310 can include one or more regions with fan-out vias 402. In some cases, the fan-out vias 402 can provide electrical communication between the first and second redistribution layers 302-1 and 302-2 for the second package 106-2 (each of FIG. 3). The chip layer 310 can also or instead include one or more regions for fundamental passive components, such as a capacitor. In FIGS. 4-1 and 4-2, these regions are referred to as capacitor regions 404 and 406 (cap region 404 and cap region 406) by way of example and without limitation. At least one capacitor can be disposed in one or more of any of these capacitor regions. Examples of capacitors being included in these regions are described below with reference to FIG. 4-2.

In some cases, like the example shown in FIG. 4-1, the chip layer 310 omits fan-out vias adjacent to the cap regions 406 in the volume(s) located between the second chip edge 314-2 and the second package edge 316-2. However, fan-out vias can instead be included in these volumes. In some cases, like the example shown in FIG. 4-1, the fan-out vias 402 that are adjacent to the cap regions 404 in the volume(s) between the first chip edge 314-1 and the first package edge 316-1 are separated from the capacitors based on distance from the first chip edge 314-1. In other cases, however, the interconnect vias and the capacitors can be intermingled in one region at various distances from the first chip edge 314-1. Examples of these different approaches are described below reference to FIGS. 5-1 to 5-3. A cross-sectional view of the first package 106-1 (and the second package 106-2) that is depicted in FIG. 5 is indicated in FIG. 4-1 where fan-out vias are present. A cross-sectional view of the first package 106-1 (and the second package 106-2) that is depicted in FIG. 6 is indicated in FIG. 4-1 where fan-out vias are not present.

Continuing with reference to FIG. 4-2, multiple capacitors 108 are depicted in the capacitor regions 404 and 406. An example of an interconnect via 304 and a capacitor 108 that are aligned with respect to the line 308 is also shown. In FIG. 4-2, the interconnect via 304 and the capacitor 108 are centered on the line 308; however, either or both components may overlap the line 308 without being centered thereon. In the capacitor regions 406, two capacitors 108 are illustrated as being disposed between the second chip edge 314-2 and the second package edge 316-2. In other examples, however, one capacitor 108 or more than two capacitors 108 may be so disposed. In the capacitor regions 404, one capacitor 108 is disposed between the first chip edge 314-1 and the first package edge 316-1. In other examples, however, more than one capacitor 108 may be so disposed. Generally, any quantity of capacitors 108 may be disposed in any capacitor region 404 or 406 in any arrangement. Similarly, any quantity of interconnect vias 304 may be disposed in any fan-out via region 402 in any arrangement.

In example implementations, the first chip edge 314-1 of the first IC chip 306-1 can be substantially perpendicular to the second chip edge 314-2 of the first IC chip 306-1. The first package edge 316-1 of the first package 106-1 can be substantially perpendicular to the second package edge 316-2 of the first package 106-1. Further, the second package edge 316-2 can be substantially parallel to the second chip edge 314-2 of the first IC chip 306-1. A first capacitor 108-1 can be disposed between the first chip edge 314-1 of the first IC chip 306-1 and the first package edge 316-1 of the first package 106-1. A second capacitor 108-2 that is disposed in the chip layer 310 can be disposed between the second chip edge 314-2 of the first IC chip 306-1 and the second package edge 316-2 of the first package 106-1.

In some aspects, the first package 106-1 includes a first volume 412-1 located between the first chip edge 314-1 and the first package edge 316-1. The first volume 412-1 includes a first fan-out region that corresponds to the second IC chip 306-2 (e.g., of FIGS. 3, 5, and 6). The first package 106-1 also includes a second volume 412-2 located between the second chip edge 314-2 and the second package edge 316-2, but exclusive of the first volume 412-1. The second volume 412-2 includes a second fan-out region that corresponds to the first IC chip 306-1. By way of example only, the capacitors 108 in the first and second volumes 412-1 and 412-2 can realize decoupling capacitors 108 for the second IC chip 306-2 of the second package 106-2 (e.g., of FIGS. 3, 5, and 6). For instance, the first capacitor 108-1 can provide a first decoupling capacitor 108-1 for the second IC chip 306-2, and the second capacitor 108-2 can provide a second decoupling capacitor 108-2 for the second IC chip 306-2. As shown in FIG. 4-2, the second volume 412-2 may lack interconnect vias in some implementations.

FIG. 5 illustrates a cross-section view 500 of an example PoP assembly 104 that depicts interconnect vias 304 in the chip layer 310 in conjunction with at least one capacitor 108 from the perspective of a front view. As illustrated for a cross-sectional front view (as also denoted in FIGS. 4-1 and 4-2), the chip layer 310 includes fan-out via spaces 402 at the external or edge portions of the first and second redistribution layers 302-1 and 302-2. In example implementations, each fan-out via space 402 includes at least one interconnect via 304. The fan-out via spaces 402 are illustrated as being electrically coupled between the first redistribution layer 302-1 and the second redistribution layer 302-2. Each associated interconnect via 304 may likewise be coupled between the first redistribution layer 302-1 and the second redistribution layer 302-2 (not explicitly depicted with respect to the interconnect via 304 in FIG. 5).

To match the example architectures of FIGS. 4-1 and 4-2, each capacitor 108 is disposed within the chip layer 310 between a first chip edge 314-1 of the first IC chip 306-1 and an interconnect via 304 of the fan-out via space 402. The interconnect via 304 is disposed within the chip layer 310 between the capacitor 108 and the first package edge 316-1 of the first package 106-1. In some cases, the capacitor 108 and the interconnect via 304 are disposed along a line 308 that is substantially perpendicular to the first chip edge 314-1 of the first IC chip 306-1 and/or to the first package edge 316-1 of the first package 106-1. However, the quantity, order, and/or or arrangements of the capacitor(s) 108 and the interconnect via(s) 304 may be different. Alternative examples are described next with reference to FIGS. 5-1 to 5-3.

FIGS. 5-1, 5-2, and 5-3 illustrate cross-section views 500-1, 500-2, and 500-3, respectively, of an example PoP assembly 104 (e.g., also of FIG. 5) that depict example implementations for interconnect vias 304 and capacitors 108 in the chip layer 310. In FIGS. 5-1 to 5-3, the fan-out via spaces 402 are not explicitly indicated for clarity. By way of example only, certain capacitors 108 in FIGS. 5-1 to 5-3 are shown being coupled to the second ball grid array 318-2 that connects the first package 106-1 to the second package 106-2 via the second redistribution layer 302-2.

In FIG. 5-1, two alternative examples are shown. On the “left” (as depicted) of the first IC chip 306-1, a capacitor 108 is disposed between the first IC chip 306-1 and a first interconnect via 304-1, which is similar to the arrangement of FIG. 5. However, a second interconnect via 304-2 is also disposed in the chip layer 310 on the left side. Thus, two interconnect vias 304-1 and 304-2 are disposed between the capacitor 108 and the first package edge 316-1 of the first package 106-1. On the “right” (as depicted) of the first IC chip 306-1 in FIG. 5-1, a capacitor 108 and an interconnect via 304 are disposed between the first IC chip 306-1 and an edge or end of the two redistribution layers, which is similar to the arrangement of FIG. 5. However, the interconnect via 304 is closer to the first IC chip 306-1 than is the capacitor 108. Thus, the interconnect via 304 is disposed between an edge of the first IC chip 306-1 and the capacitor 108. And the capacitor 108 is disposed between the interconnect via 304 and a package edge of the first package 106-1.

In FIG. 5-2, two additional alternative examples are shown. On the “left” (as depicted) of the first IC chip 306-1, a capacitor 108 and two interconnect vias 304 are disposed between the first chip edge 314-1 and the first package edge 316-1, which is similar to the arrangement of FIG. 5-1. However, the capacitor 108 is nearest the first package edge 316-1 amongst the three illustrated components. Thus, the first and second interconnect vias 304-1 and 304-2 are disposed between the first chip edge 314-1 and the capacitor 108. The capacitor 108 is disposed between the two interconnect vias 304-1 and 304-2 and the first package edge 316-1. On the “right” (as depicted) of the first IC chip 306-1 in FIG. 5-2, two capacitors 108 are disposed between the first IC chip 306-1 and the package edge of the first package 106-1 on the “right” side of the first IC chip 306-1. Thus, in this example, the chip layer 310 has at least one interconnect via 304 on one side of the first IC chip 306-1 but lacks interconnect vias 304 on the other side of the first IC chip 306-1, at least at the line 308.

In FIG. 5-3, two other alternative examples are shown. On the “left” (as depicted) of the first IC chip 306-1, a capacitor 108 and two interconnect vias 304 are disposed between the first chip edge 314-1 and the first package edge 316-1, which is similar to the arrangements of FIGS. 5-1 and 5-2. However, the capacitor 108 is disposed between the two interconnect vias 304. Thus, the first interconnect via 304-1 is disposed between the first chip edge 314-1 and the capacitor 108. The capacitor 108 is disposed between the first interconnect via 304-1 and the second interconnect via 304-2. The second interconnect via 304-2 is disposed between the capacitor 108 and the first package edge 316-1. On the “right” (as depicted) of the first IC chip 306-1 in FIG. 5-3, two interconnect vias 304 are disposed between the first IC chip 306-1 and the edges of the two redistribution layers 302 on the same side of the first IC chip 306-1. Thus, in this example, the chip layer 310 has multiple interconnect vias 304 on one side of the first IC chip 306-1 but lacks a capacitor 108 on that side, at least along the line 308 that is perpendicular to the chip edge and the package edge on that side and that extends through the two interconnect vias 304. Other alternatives for the chip layer 310 and the architectures of FIGS. 5 to 5-3 may be implemented.

FIG. 6 illustrates a cross-section view 600 of an example PoP assembly 104 that depicts the absence of interconnect vias 304 in the chip layer 310 in conjunction with at least one capacitor 108 from the perspective of a side view. As illustrated for a cross-sectional side view (the side view is also denoted in FIGS. 4-1 and 4-2), the chip layer 310 includes no fan-out via spaces 402 at this cross-section and view perspective between opposite external or edge portions of the first and second redistribution layers 302-1 and 302-2. However, each volume between the two redistribution layers 302 can include at least one capacitor 108. To match the example architectures of FIGS. 4-1 and 4-2, each capacitor 108 is disposed within the chip layer 310 between a second chip edge 314-2 of the first IC chip 306-1 and the second package edge 316-2 of the first package 106-1. The quantity, order, and/or or arrangements of the capacitor(s) 108 may be different from that which is illustrated. Further, in some cases, the depicted spaces can include at least one interconnect via 304. Alternative examples are described next with reference to FIG. 6-1.

FIG. 6-1 illustrates a cross-section view 600-1 of an example PoP assembly 104 of FIG. 6 that depicts an example implementation for capacitors 108 in the chip layer 310. In this example, two capacitors 108 are disposed between the second chip edge 314-2 of the first IC chip 306-1 and the second package edge 316-2 of the first package 106-1. As shown, the two or more capacitors 108 may have different sizes and/or capacitances. Further, the two capacitors 108 may be coupled together in parallel with each other and with the second IC chip 306-2 of the second package 106-2 between a supply voltage rail and a ground of a power distribution network (PDN) for at least the second IC chip 306-2. As illustrated on the “right” side of the first IC chip 306-1, no capacitors may be present in the corresponding volume or no capacitors that are present may be visible from the cross-section location given the view direction.

FIG. 7 illustrates a cross-section view 700 of an example PoP assembly 104 with a first package 106-1 (e.g., a base package) including an SoC and a second package 106-2 (e.g., an upper package) including a memory device, such as one or more dynamic random-access memory (DRAM) chips. In the chip layer 310, there is a capacitor 108 disposed between the SoC and the first and second interconnect vias 304-1 and 304-2. On the other side of the SoC, first and second capacitors 108-1 and 108-2 are disposed in the chip layer 310 between a chip edge of the SoC and a package edge of the first package 106-1. In some example implementations, realizations can be transparent to SoC fan-out package design as no SoC/PCB routing resource need be tapped. Additionally or alternatively, with certain described implementations, the assembly structure can be manufactured with a photo-mask design modification using common existing process steps instead of a customized process.

Having generally described schemes, techniques, and hardware for implementing efficient fanout space utilization in a PoP assembly, this discussion now turns to example methods.

### Example Methods

FIG. 8 is a flow diagram illustrating an example process 800 for manufacturing a PoP assembly that efficiently utilizes fan-out space. The flow chart 800 includes two blocks 802 and 804. The operations of example processes can be performed to produce a PoP assembly 104 as described herein, which PoP assembly 104 can be mounted on a support structure 202 and/or incorporated into an apparatus, such as an electronic device.

At block 802, a first package having a first side and a second side is provided, with the first side configured to be connected to a support structure. The first package includes a first integrated circuit (IC) chip that defines a chip layer of the first package, with the first IC chip having a chip edge. The first package also includes an interconnect via disposed in the chip layer. The first package further includes a capacitor disposed in the chip layer, with the capacitor and the interconnect via disposed along a line that is substantially perpendicular to the chip edge of the first IC chip.

For example, a first package 106-1 having a first side 312-1 and a second side 312-2 can be provided, with the first side 312-1 configured to be connected to a support structure 202. The first package 106-1 can include a first IC chip 306-1 that defines a chip layer 310 of the first package 106-1, with the first IC chip 306-1 having a chip edge 314. The first package 106-1 can also include an interconnect via 304 disposed in the chip layer 310. The first package 106-1 can further include a capacitor 108 that is disposed in the chip layer 310. The capacitor 108 and the interconnect via 304 can be disposed along a line 308 that is substantially perpendicular to the chip edge 314 of the first IC chip 306-1.

The capacitor 108 may be disposed, for instance, between the chip edge 314 of the first IC chip 306-1 and the interconnect via 304. By disposing at least one capacitor 108 and at least one interconnect via 304 along a line 308 as described herein, fan-out space can be efficiently utilized—e.g., instead of limiting component placement along such a line solely to a capacitor. Thus, the placement of interconnect vias 304 may be unaffected, or at least not reduced in quantity, by incorporating a capacitor 108 in the fan-out area.

At block 804, a second package having a first side is provided, with the first side of the second package configured to be connected to the second side of the first package and with the second package including a second IC chip. For example, a second package 106-2 having a first side 312-1 can be provided. The first side 312-1 of the second package 106-2 can be configured to be connected to the second side 312-2 of the first package 106-1. The second package 106-2 can include a second IC chip 306-2. Here, the first IC chip 306-1 may be realized with an SoC, and the second IC chip 306-2 may be realized with a DRAM chip.

In example implementations, the first side 312-1 of the first package 106-1 can be connected to the support structure 202 using a first ball grid array 318-1. Similarly, the first side 312-1 of the second package 106-2 can be connected to the second side 312-2 of the first package 106-1 using a second ball grid array 318-2. In some cases, the connecting of the second package 106-2 to the first package 106-1 can include coupling the capacitor 108 to a power distribution network of the second IC chip 306-2 of the second package 106-2.

Aspects of these methods may be implemented in, for example, hardware (e.g., fixed logic circuitry, a controller, a finite state machine, or a processor in conjunction with a memory), firmware, software, or some combination thereof. The methods may be realized to produce one or more of the apparatuses or components shown in FIGS. 1 to 7 and 9, which components may be further divided, combined, and so on. The devices and components of these figures generally represent hardware, such as electronic devices, PCBs, packaged modules, IC chips, components, or circuits; firmware; software; or a combination thereof. Thus, these figures illustrate some of the many possible systems or apparatuses capable of being produced using the described methods.

For the methods described herein and the associated flow chart(s) and/or flow diagram(s), the orders in which operations are shown and/or described are not intended to be construed as a limitation. Instead, any number or combination of the described method operations can be combined in any order to implement a given method or an alternative method, including by combining operations from different ones of the flow chart(s) and flow diagram(s) and the earlier-described schemes and techniques into one or more methods. Operations may also be omitted from or added to the described methods. Further, described operations can be implemented in fully or partially overlapping manners.

### Additional Example Apparatuses and Electronic Devices

FIG. 9 illustrates various components of an example electronic device 900 that can implement efficient fan-out space utilization in PoP assemblies in accordance with one or more described aspects. The electronic device 900 may be implemented as any one or combination of a fixed, mobile, stand-alone, or embedded device or in any form of a consumer, computer, portable, user, server, communication, phone, navigation, gaming, audio, camera, messaging, media playback, and/or other type of electronic device 900, such as the smartphone that is depicted in FIG. 1 as the apparatus 102. One or more of the illustrated components may be realized as discrete components or as integrated components on at least one integrated circuit of the electronic device 900 or separately or jointly in one or more packages of the electronic device 900.

The electronic device 900 can include one or more communication transceivers 902 that enable wired and/or wireless communication of device data 904, such as received data, transmitted data, or other information identified above. Example communication transceivers 902 include near-field communication (NFC) transceivers, wireless personal area network (PAN) (WPAN) radios compliant with various IEEE 802.15 (Bluetooth®) standards, wireless local area network (LAN) (WLAN) radios compliant with any of the various IEEE 802.11 (Wi-Fi®) standards, wireless wide area network (WAN) (WWAN) radios (e.g., those that are 3GPP-compliant) for cellular telephony, wireless metropolitan area network (MAN) (WMAN) radios compliant with various IEEE 802.16 (WiMAX™) standards, infrared (IR) transceivers compliant with an Infrared Data Association (IrDA) protocol, and wired local area network (LAN) (WLAN) Ethernet transceivers.

The electronic device 900 may also include one or more data input ports 906 via which any type of data, media content, and/or other inputs can be received, such as user-selectable inputs, messages, applications, music, television content, recorded video content, and any other type of audio, video, and/or image data received from any content and/or data source, including a sensor like a microphone or a camera. The data input ports 906 may include USB ports, coaxial cable ports, fiber optic ports for optical fiber interconnects or cabling, and other serial or parallel connectors (including internal connectors) for flash memory, DVDs, CDs, and the like. These data input ports 906 may be used to couple the electronic device to components, peripherals, or accessories such as keyboards, microphones, cameras, or other sensors.

The electronic device 900 of this example includes at least one processor 908 (e.g., any one or more of application processors, microprocessors, digital-signal processors (DSPs), controllers, and the like), which can include a combined processor and memory system (e.g., implemented as part of an SoC), that processes (e.g., executes) computer-executable instructions to control operation of the device. The processor 908 may be implemented as an application processor, embedded controller, microcontroller, security processor, artificial intelligence (AI) accelerator, and the like. Generally, a processor or processing system may be implemented at least partially in hardware, which can include components of an integrated circuit or on-chip system, a digital signal processor (DSP), an application-specific integrated circuit (ASIC), a field programmable gate array (FPGA), a complex programmable logic device (CPLD), and other implementations in silicon and/or other materials.

Alternatively or additionally, the electronic device 900 can be implemented with any one or combination of electronic circuitry, which may include software, hardware, firmware, or fixed logic circuitry that is implemented in connection with processing and control circuits, which are generally indicated at 910 (as electronic circuitry 910). This electronic circuitry 910 can implement executable or hardware-based modules (not shown in FIG. 9), such as through processing/computer-executable instructions stored on computer-readable media, through logic circuitry and/or hardware (e.g., such as an FPGA), and so forth.

The electronic device 900 can include a system bus, interconnect, crossbar, data transfer system, switch fabric, or other communication fabric that couples the various components within the device. A system bus or interconnect can include any one or a combination of different bus structures, such as a memory bus or memory controller, a peripheral bus, a universal serial bus (USB), and/or a processor or local bus that utilizes any of a variety of bus architectures.

The electronic device 900 also includes one or more memory devices 912 that enable data storage, examples of which include random-access memory (RAM), non-volatile memory (e.g., read-only memory (ROM), flash memory, EPROM, and EEPROM), and a disk storage device. Thus, the memory device(s) 912 can be distributed across different logical storage levels of a system as well as at different physical components. The memory device(s) 912 provide data storage mechanisms to store the device data 904, other types of code and/or data, and various device applications 920 (e.g., software applications or programs). For example, an operating system 914 can be maintained as software instructions within the memory device 912 and executed by the processor 908.

In some implementations, the electronic device 900 also includes an audio and/or video processing system 916 that processes audio and/or video data and/or that passes through the audio and/or video data to an audio system 918 and/or to a display system 922 (e.g., a video buffer or a screen of a smartphone or camera). The audio system 918 and/or the display system 922 may include any devices that process, display, and/or otherwise render audio, video, display, and/or image data. Display data and audio signals can be communicated to an audio component and/or to a display component via an RF (radio-frequency) link, an S-video link, an HDMI (high-definition multimedia interface) link, a composite video link, a component video link, a DVI (digital video interface) link, an analog audio connection, a video bus, or another similar communication link, such as a media data port 924. In some implementations, the audio system 918 and/or the display system 922 are external or separate components of the electronic device 900. Alternatively, the display system 922, for example, can be an integrated component of the example electronic device 900, such as part of an integrated touch interface.

The electronic device 900 of FIG. 9 illustrates example implementations of the apparatus 102 of FIG. 1, of an apparatus that may include a PoP assembly 104 of any of the FIGS. 2 to 7, or some combination thereof. Accordingly, one of the components illustrated in FIG. 9 may be realized as part of a first package 106-1 (e.g., of earlier figures), and another one of the components of FIG. 9 may be realized as part of a second package 106-2. For example, as indicated by the arrows 926, the processor 908 may realize a first IC chip 306-1 of a first package 106-1, and the memory device 912 may realize a second IC chip 306-2 of a second package 106-2.

### Example Aspects and Implementations for Efficient Fan-Out Space Utilization in a PoP Assembly

In the following, some examples, example aspects, and implementations are described:
Example aspect 1: An apparatus for efficient space utilization with a package-on-package (PoP) assembly, the apparatus comprising: a first package having a first side and a second side, the first side configured to be connected to a support structure, the first package including: a first integrated circuit (IC) chip that defines a chip layer of the first package, the first IC chip having a chip edge; an interconnect via disposed in the chip layer; and a capacitor disposed in the chip layer, the capacitor and the interconnect via disposed along a line that is substantially perpendicular to the chip edge of the first IC chip; and a second package having a first side, the first side of the second package configured to be connected to the second side of the first package, the second package including a second IC chip.
Example aspect 2: The apparatus of example aspect 1 or any one or more of the examples described herein, wherein: the first side of the second package is connected to the second side of the first package; and the capacitor is coupled to the second IC chip.
Example aspect 3: The apparatus of example aspect 2 or any one or more of the examples described herein, wherein: the capacitor comprises a decoupling capacitor for the second IC chip.
Example aspect 4: The apparatus of example aspect 1 or any one or more of the examples described herein, wherein: the first package includes: a first redistribution layer; and a second redistribution layer, the chip layer disposed between the first redistribution layer and the second redistribution layer; and the interconnect via is coupled between the first redistribution layer and the second redistribution layer.
Example aspect 5: The apparatus of example aspect 4 or any one or more of the examples described herein, wherein: the interconnect via is configured to provide at least part of an electrical pathway between the second IC chip and at least one of the first IC chip or the support structure.
Example aspect 6: The apparatus of example aspect 1 or any one or more of the examples described herein, wherein: the first package has a package edge, the package edge substantially parallel to the chip edge of the first IC chip; and the capacitor and the interconnect via are disposed along the line between the chip edge of the first IC chip and the package edge of the first package.
Example aspect 7: The apparatus of example aspect 6 or any one or more of the examples described herein, wherein: the capacitor is disposed in the first package between the chip edge of the first IC chip and the interconnect via; and the interconnect via is disposed in the first package between the capacitor and the package edge of the first package.
Example aspect 8: The apparatus of example aspect 6 or any one or more of the examples described herein, wherein: the interconnect via is disposed in the first package between the chip edge of the first IC chip and the capacitor; and the capacitor is disposed in the first package between the interconnect via and the package edge of the first package.
Example aspect 9: The apparatus of example aspect 6 or any one or more of the examples described herein, wherein: the interconnect via that is disposed in the chip layer of the first package comprises a first interconnect via; the first package includes a second interconnect via that is disposed in the chip layer of the first package; and the capacitor, the first interconnect via, and the second interconnect via are disposed along the line between the chip edge of the first IC chip and the package edge of the first package.
Example aspect 10: The apparatus of example aspect 9 or any one or more of the examples described herein, wherein: the capacitor is disposed in the chip layer of the first package between the chip edge of the first IC chip and the first and second interconnect vias.
Example aspect 11: The apparatus of example aspect 9 or any one or more of the examples described herein, wherein: the capacitor is disposed in the chip layer of the first package between the first and second interconnect vias and the package edge of the first package.
Example aspect 12: The apparatus of example aspect 9 or any one or more of the examples described herein, wherein: the capacitor is disposed in the chip layer of the first package between the first interconnect via and the second interconnect via.
Example aspect 13: The apparatus of example aspect 1 or any one or more of the examples described herein, wherein: the chip edge of the first IC chip comprises a first chip edge; the first IC chip has a second chip edge substantially perpendicular to the first chip edge; the first package has a first package edge and a second package edge, the second package edge substantially parallel to the second chip edge of the first IC chip; the capacitor comprises a first capacitor; the first capacitor is disposed between the first chip edge of the first IC chip and the first package edge of the first package; and the first package includes a second capacitor disposed in the chip layer, the second capacitor disposed between the second chip edge of the first IC chip and the second package edge of the first package.
Example aspect 14: The apparatus of example aspect 13 or any one or more of the examples described herein, wherein: the first package includes a first volume located between the first chip edge and the first package edge, the first volume comprising a first fan-out region that corresponds to the second IC chip; and the first package includes a second volume located between the second chip edge and the second package edge, the second volume comprising a second fan-out region that corresponds to the first IC chip.
Example aspect 15: The apparatus of example aspect 14 or any one or more of the examples described herein, wherein: the first capacitor comprises a first decoupling capacitor for the second IC chip; and the second capacitor comprises a second decoupling capacitor for the second IC chip.
Example aspect 16: The apparatus of example aspect 14 or any one or more of the examples described herein, wherein: the second volume lacks interconnect vias.
Example aspect 17: A method for manufacturing a space-efficient package-on-package (PoP) assembly, the method comprising: providing a first package having a first side and a second side, the first side configured to be connected to a support structure, the first package including: a first integrated circuit (IC) chip that defines a chip layer of the first package, the first IC chip having a chip edge; an interconnect via disposed in the chip layer; and a capacitor disposed in the chip layer, the capacitor and the interconnect via disposed along a line that is substantially perpendicular to the chip edge of the first IC chip; and providing a second package having a first side, the first side of the second package configured to be connected to the second side of the first package, the second package including a second IC chip.
Example aspect 18: The method of example aspect 17 or any one or more of the examples described herein, further comprising: providing the support structure; connecting the first side of the first package to the support structure using a first ball grid array; and connecting the first side of the second package to the second side of the first package using a second ball grid array.
Example aspect 19: The method of example aspect 18 or any one or more of the examples described herein, wherein the connecting of the second package to the first package comprises: coupling the capacitor to a power distribution network of the second IC chip of the second package.
Example aspect 20: An apparatus for efficient space utilization with a package-on-package (PoP) assembly, the apparatus comprising: a support structure; a first package having a first side and a second side, the first side connected to the support structure, the first package including: a package edge; a first redistribution layer disposed closer to the first side than the second side; a second redistribution layer disposed closer to the second side than the first side; a chip layer disposed between the first redistribution layer and the second redistribution layer, the chip layer including: a first integrated circuit (IC) chip having a chip edge that is substantially parallel to the package edge; an interconnect via disposed between the chip edge and the package edge; and a decoupling capacitor disposed between the chip edge and the package edge, the decoupling capacitor and the interconnect via disposed along a line that is substantially perpendicular to the chip edge and the package edge; and a second package having a first side, the first side of the second package connected to the second side of the first package, the second package including a second IC chip that is coupled to the decoupling capacitor.
Example aspect 21: An apparatus comprising: a first package including first circuitry, a first side, a second side, and at least one circuit component, the first side configured to be coupled to a printed circuit board (PCB); and a second package including second circuitry and a first side, the first side of the second package coupled to the second side of the first package, the at least one circuit component coupled to the second circuitry of the second package.
Example aspect 22: The apparatus of example aspect 21 or any one or more of the examples described herein, wherein: the at least one circuit component comprises at least one capacitor.
Example aspect 23: The apparatus of example aspect 22 or any one or more of the examples described herein, wherein: the at least one capacitor comprises a decoupling capacitor.
Example aspect 24: The apparatus of example aspect 22 or any one or more of the examples described herein, wherein: the at least one capacitor is coupled to a ground and a power distribution network of the apparatus.
Example aspect 25: The apparatus of example aspect 24 or any one or more of the examples described herein, wherein: the at least one capacitor is coupled between the ground and the power distribution network and in parallel with the second circuitry of the second package.
Example aspect 26: The apparatus of example aspect 21 or any one or more of the examples described herein, wherein: the apparatus comprises a package-on-package (POP) assembly.
Example aspect 27: The apparatus of example aspect 21 or any one or more of the examples described herein, wherein: the first circuitry comprises logic; and the second circuitry comprises memory.
Example aspect 28: The apparatus of example aspect 27 or any one or more of the examples described herein, wherein: the logic comprises a system-on-chip (SoC); and the memory comprises dynamic random-access memory (DRAM).
Example aspect 29: The apparatus of example aspect 21 or any one or more of the examples described herein, wherein: the at least one circuit component is coupled to the second circuitry of the second package through at least one redistribution layer of the first package, the at least one redistribution layer (RDL) disposed between the first circuitry and the second circuitry.
Example aspect 30: The apparatus of example aspect 29 or any one or more of the examples described herein, wherein: the at least one circuit component is coupled to the second circuitry of the second package using at least one electrical path that traverses through the at least one redistribution layer of the first package, the at least one electrical path avoiding at least one other redistribution layer that is disposed between the first circuitry of the first package and the first side of the first package.
Example aspect 31: The apparatus of example aspect 30 or any one or more of the examples described herein, further comprising: at least one ball grid array (BGA), the at least one ball grid array coupling the second side of the first package to the first side of the second package, the electrical path including at least one ball of the at least one ball grid array.
Example aspect 32: The apparatus of example aspect 21 or any one or more of the examples described herein, wherein: the first circuitry defines a first plane; the second circuitry defines a second plane different from the first plane; and the at least one circuit component is disposed in the first plane.
Example aspect 33: The apparatus of example aspect 32 or any one or more of the examples described herein, wherein: a height of the first circuitry is greater than a height of the at least one circuit component, the heights defined substantially perpendicular to the first plane.
Example aspect 34: The apparatus of example aspect 21 or any one or more of the examples described herein, wherein: the first package includes a fan-out area extending from at least one edge of the first circuitry; and the at least one circuit component is disposed in the fan-out area.
Example aspect 35: The apparatus of example aspect 34 or any one or more of the examples described herein, wherein: the first package includes multiple circuit components.
Example aspect 36: The apparatus of example aspect 35 or any one or more of the examples described herein, wherein: at least two circuit components of the multiple circuit components are disposed in the fan-out area between a same edge of the first circuitry and an edge of the first package.
Example aspect 37: The apparatus of example aspect 35 or any one or more of the examples described herein, wherein: a first circuit component of the multiple circuit components is disposed in the fan-out area between a first edge of the first circuitry and a first edge of the first package; and a second circuit component of the multiple circuit components is disposed in the fan-out area between a second edge of the first circuitry and a second edge of the first package.
Example aspect 38: The apparatus of example aspect 34 or any one or more of the examples described herein, wherein: at least part of the fan-out area is filled with molding material; and the at least one circuit component is disposed within the molding material.
Example aspect 39: The apparatus of example aspect 38 or any one or more of the examples described herein, wherein: the fan-out includes at least one interconnect disposed in the molding; and the at least one circuit component is disposed between the at least one interconnect and the at least one edge of the first circuitry of the first package.
Example aspect 40: The apparatus of example aspect 39 or any one or more of the examples described herein, wherein: the second circuitry of the second package is coupled to a ball grid array through the at least one interconnect, the ball grid array configured to couple the first package and the second package to the printed circuit board.
Example aspect 41: The apparatus of example aspect 40 or any one or more of the examples described herein, wherein: the at least one interconnect comprises a package-on-package fan-out via.
Example aspect 42: The apparatus of example aspect 34 or any one or more of the examples described herein, wherein: the fan-out area extends from the at least one edge of the first circuitry to at least one corresponding edge of the first package; and the at least one circuit component is disposed between the at least one edge of the first circuitry and the at least one corresponding edge of the first package.
Example aspect 43: The apparatus of example aspect 42 or any one or more of the examples described herein, wherein: the first package includes a first redistribution layer disposed between the first side of the first package and the first circuitry; the first package includes a second redistribution layer disposed between the second side of the first package and the first circuitry; and the at least one circuit component is disposed between the first redistribution layer and the second redistribution layer.
Example aspect 44: The apparatus of example aspect 43 or any one or more of the examples described herein, wherein: the second redistribution layer of the first package is disposed between the first circuitry and a ball grid array configured to coupled the first package and the second package to the printed circuit board.
Example aspect 45: An apparatus comprising: a processor or processor and memory configured to perform the method of any one of example aspects 17-19 or any one or more of the examples described herein.

Features described in the context of one example aspect (e.g., a method or an apparatus) may be used in combination with other example aspects (e.g., an apparatus or a method, respectively, or a different method or a different apparatus).

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a−b, a−c, b−c, and a−b−c, as well as any combination with multiples of the same element (e.g., a−a, a−a−a, a−a−b, a−a−c, a−b−b, a−c−c, b−b, b−b−b, b−b−c, c−c, and c−c−c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for realizing efficient fanout space utilization in a PoP assembly have been described in language specific to certain features and/or methods, the subject of the appended claims is not necessarily limited to the specific features or methods described. Rather, the specific features and methods are disclosed as example implementations for realizing efficient fanout space utilization in a PoP assembly.

What is claimed is:

1. An apparatus for efficient space utilization with a package-on-package (PoP) assembly, the apparatus comprising:
a first package having a first side and a second side, the first side configured to be connected to a support structure, the first package including:
a first integrated circuit (IC) chip that defines a chip layer of the first package, the first IC chip having a chip edge;
an interconnect via disposed in the chip layer; and
a capacitor disposed in the chip layer, the capacitor and the interconnect via disposed along a line that is substantially perpendicular to the chip edge of the first IC chip; and
a second package having a first side, the first side of the second package configured to be connected to the second side of the first package, the second package including a second IC chip.

2. The apparatus of claim 1, wherein:
the first side of the second package is connected to the second side of the first package; and
the capacitor is coupled to the second IC chip.

3. The apparatus of claim 2, wherein:
the capacitor comprises a decoupling capacitor for the second IC chip.

4. The apparatus of claim 1, wherein:
the first package includes:
a first redistribution layer; and
a second redistribution layer, the chip layer disposed between the first redistribution layer and the second redistribution layer; and
the interconnect via is coupled between the first redistribution layer and the second redistribution layer.

5. The apparatus of claim 4, wherein:
the interconnect via is configured to provide at least part of an electrical pathway between the second IC chip and at least one of the first IC chip or the support structure.

6. The apparatus of claim 1, wherein:
the first package has a package edge, the package edge substantially parallel to the chip edge of the first IC chip; and
the capacitor and the interconnect via are disposed along the line between the chip edge of the first IC chip and the package edge of the first package.

7. The apparatus of claim 6, wherein:
the capacitor is disposed in the first package between the chip edge of the first IC chip and the interconnect via; and
the interconnect via is disposed in the first package between the capacitor and the package edge of the first package.

8. The apparatus of claim 6, wherein:
the interconnect via is disposed in the first package between the chip edge of the first IC chip and the capacitor; and
the capacitor is disposed in the first package between the interconnect via and the package edge of the first package.

9. The apparatus of claim 6, wherein:
the interconnect via that is disposed in the chip layer of the first package comprises a first interconnect via;
the first package includes a second interconnect via that is disposed in the chip layer of the first package; and
the capacitor, the first interconnect via, and the second interconnect via are disposed along the line between the chip edge of the first IC chip and the package edge of the first package.

10. The apparatus of claim 9, wherein:
the capacitor is disposed in the chip layer of the first package between the chip edge of the first IC chip and the first and second interconnect vias.

11. The apparatus of claim 9, wherein:
the capacitor is disposed in the chip layer of the first package between the first and second interconnect vias and the package edge of the first package.

12. The apparatus of claim 9, wherein:
the capacitor is disposed in the chip layer of the first package between the first interconnect via and the second interconnect via.

13. The apparatus of claim 1, wherein:
the chip edge of the first IC chip comprises a first chip edge;
the first IC chip has a second chip edge substantially perpendicular to the first chip edge;
the first package has a first package edge and a second package edge, the second package edge substantially parallel to the second chip edge of the first IC chip;
the capacitor comprises a first capacitor;
the first capacitor is disposed between the first chip edge of the first IC chip and the first package edge of the first package; and
the first package includes a second capacitor disposed in the chip layer, the second capacitor disposed between the second chip edge of the first IC chip and the second package edge of the first package.

14. The apparatus of claim 13, wherein:
the first package includes a first volume located between the first chip edge and the first package edge, the first volume comprising a first fan-out region that corresponds to the second IC chip; and
the first package includes a second volume located between the second chip edge and the second package edge, the second volume comprising a second fan-out region that corresponds to the first IC chip.

15. The apparatus of claim 14, wherein:
the first capacitor comprises a first decoupling capacitor for the second IC chip; and
the second capacitor comprises a second decoupling capacitor for the second IC chip.

16. The apparatus of claim 14, wherein:
the second volume lacks interconnect vias.

17. A method for manufacturing a space-efficient package-on-package (PoP) assembly, the method comprising:
providing a first package having a first side and a second side, the first side configured to be connected to a support structure, the first package including:
a first integrated circuit (IC) chip that defines a chip layer of the first package, the first IC chip having a chip edge;
an interconnect via disposed in the chip layer; and
a capacitor disposed in the chip layer, the capacitor and the interconnect via disposed along a line that is substantially perpendicular to the chip edge of the first IC chip; and
providing a second package having a first side, the first side of the second package configured to be connected to the second side of the first package, the second package including a second IC chip.

18. The method of claim 17, further comprising:
providing the support structure;
connecting the first side of the first package to the support structure using a first ball grid array; and
connecting the first side of the second package to the second side of the first package using a second ball grid array.

19. The method of claim 18, wherein the connecting of the second package to the first package comprises:
coupling the capacitor to a power distribution network of the second IC chip of the second package.

20. An apparatus for efficient space utilization with a package-on-package (PoP) assembly, the apparatus comprising:
a support structure;
a first package having a first side and a second side, the first side connected to the support structure, the first package including:
a package edge;
a first redistribution layer disposed closer to the first side than the second side;
a second redistribution layer disposed closer to the second side than the first side;
a chip layer disposed between the first redistribution layer and the second redistribution layer, the chip layer including:
a first integrated circuit (IC) chip having a chip edge that is substantially parallel to the package edge;
an interconnect via disposed between the chip edge and the package edge; and
a decoupling capacitor disposed between the chip edge and the package edge, the decoupling capacitor and the interconnect via disposed along a line that is substantially perpendicular to the chip edge and the package edge; and
a second package having a first side, the first side of the second package connected to the second side of the first package, the second package including a second IC chip that is coupled to the decoupling capacitor.
